(19) United States
(12) Patent Application Publication
(10) Pub. No.: US 2026/0180522 A1
(43) Pub. Date: Jun. 25, 2026

(54) Radio-frequency amplifier circuit based on asymmetric fishbone-shaped matching network

(71) Applicant: JIASHAN FUDAN RESEARCH INSTITUTE, Jiaxing (CN)

(72) Inventors: Kefeng HAN, Jiaxing (CN); Kefeng HAN, Jiaxing (CN); Na YAN, Jiaxing (CN)

(73) Assignee: JIASHAN FUDAN RESEARCH INSTITUTE, Jiaxing (CN)

(21) Appl. No.: 19/129,838

(22) PCT Filed: Feb. 29, 2024
(86) PCT No.: PCT/CN2024/079297

§ 371 Date: May 14, 2025

(30) Foreign Application Priority Data
Sep. 14, 2023 (CN) 202311190802.9

(51) Int. Cl. H03F 3/19; H03F 1/02; H03F 1/30; H03F 1/56; H03F 3/195; H03F 3/21

(52) U.S. Cl. CPC H03F 3/19; H03F 1/0261; H03F 1/30; H03F 1/56; H03F 1/565; H03F 3/195; H03F 3/211; H03F 2200/222; H03F 2200/387; H03F 2200/451

(57) ABSTRACT

A radio-frequency power amplifier circuit based on an asymmetric fishbone-shaped matching network, comprising a power amplifier transistor. An input end of the power amplifier transistor is connected to an input matching network, and an output end of the power amplifier transistor is connected to an output matching network; the input matching network and/or the output matching network is of an asymmetric fishbone-shaped structure; the asymmetric fishbone-shaped structure comprises backbone elements which are sequentially connected in series, and connecting points between adjacent backbone elements are connected to upper-row rib elements and lower-row rib elements; the upper-row rib elements and the lower-row rib elements are asymmetric; the upper-row rib elements and the lower-row rib elements are all configured as open stubs, and the upper-row rib elements or the lower-row rib elements are quarter-wavelength open stubs at a harmonic frequency; and the backbone elements and the rib elements are all matching network elements.

### CROSS-REFERENCE

This application claims the benefit of priority from China Patent Application No. 2023111908029 filed on Sep. 14, 2023, the contents of which are hereby incorporated by reference in their entirety.

### TECHNICAL FIELD

The present invention relates to the technical field of radio-frequency communication, especially relates to a radio-frequency amplifier circuit based on asymmetric fishbone-shaped matching network.

### BACKGROUND TECHNOLOGY

The radio-frequency amplifier circuits have been widely used in radio systems for communication, navigation, recognition, observing and controlling, broadcasting, remote sensing remote observation, radio astronomy and electronic countermeasures etc. For applications such as microwave, millimeter wave communications, strict requirements have been imposed on harmonic emission power of the radio emission systems in corresponding standards; therefore, harmonic inhibition features of radio-frequency amplifier circuits become an important indicator. Currently for improvements to harmonic inhibition features of radio-frequency amplifier circuits, conventionally, integrated or independent filters are cascaded to rear ends of the radio-frequency amplifier circuits; deficiencies of the solution are that, the complexity, volume and cost for the radiofrequency amplifier circuits are increased. Therefore, a radiofrequency amplifier circuit is required to realize excellent harmonic inhibition features without increasing the structural complexity of the radiofrequency amplifier circuits.

### SUMMARY OF THE INVENTION

The present invention aims to provide a radiofrequency amplifier circuit based on asymmetric fishbone-shaped matching network, in order to reflect the harmonic elements in output signals of the radiofrequency amplifier circuits, and improve harmonic inhibition features and intermodulation inhibition features of the radiofrequency amplifier circuits.

On one aspect, the present invention provides a radiofrequency amplifier circuit based on asymmetric fishbone-shaped matching network, comprising: a power amplifier transistor, an input end of the power amplifier transistor is connected to an input matching network, and an output end of the power amplifier transistor is connected to an output matching network; the input matching network and/or the output matching network is of an asymmetric fishbone-shaped structure, and the asymmetric fishbone-shaped structure comprises backbone elements which are sequentially connected in series, and connecting points between adjacent backbone elements are configured to connect upper-row rib elements and lower-row rib elements; the upper-row rib elements and the lower-row rib elements are asymmetric; the upper-row rib elements and the lower-row rib elements are all configured as open stubs, and the upper-row rib elements or the lower-row rib elements are quarter-wavelength open stubs at a harmonic frequency; and the backbone elements and the rib elements are all matching network elements.

In a possible embodiment, all or some of the input matching network and/or the output matching network are of the asymmetric fishbone-shaped structure.

In another possible embodiment, the power amplifier transistor comprises a biased active amplifier.

In another possible embodiment, the backbone elements are configured to be inductance or transmission wires.

Beneficial effects of the radiofrequency amplifier circuit based on asymmetric fishbone-shaped matching network are: the open stub line of a one fourth wavelength at the harmonic frequencies in the radiofrequency amplifier circuits based on asymmetric fishbone matching network can reflect harmonic elements in output signals of the radiofrequency amplifier and improve the harmonic inhibition features of the radiofrequency amplifier circuits.

On the second aspect, the present invention provides a design method of the asymmetric fishbone-shaped matching network, to be used in the radiofrequency amplifier circuit based on the asymmetric fishbone-shaped matching network, comprising:
S1: designing a matching network based on LC low pass network structures, completing required port impedance conversion;
S2: calculating equivalent capacitance of quarter-wavelength open stub lines connected in parallel at harmonic frequencies under fundamental frequencies;
S3: separating capacitances connected in parallel in the LC low pass output matching network to be equivalent capacitance and residual capacitance;
S4: replacing corresponding equivalent capacitance with the quarter-wavelength open stub lines connected in parallel at the harmonic frequencies;
S5: replacing the residual capacitance with equivalent open stub lines under the fundamental frequencies and forming the asymmetric fishbone-shaped matching network.

In the present invention, a design method of “asymmetric fishbone-shaped matching network” by capacitance separation and equivalent replacement is proposed, so that the radiofrequency amplifier circuits based on the asymmetric fishbone-shaped matching network is implementable and complexity of the radiofrequency amplifier circuits is reduced.

### BRIEF DESCRIPTION OF DRAWINGS

FIG. 1 is a schematic diagram showing a radiofrequency amplifier circuit based on asymmetric fishbone-shaped matching network provided in the prior art;

FIG. 2 is a schematic diagram showing an asymmetric fishbone-shaped matching network provided in an embodiment of the present invention;

FIG. 3 is a schematic diagram showing the radiofrequency amplifier circuit based on asymmetric fishbone-shaped output matching network (AF-OMN) provided in an embodiment of the present invention;

FIG. 4 is a schematic diagram showing the radiofrequency amplifier circuit based on asymmetric fishbone-shaped input matching network (AF-IMN) provided in an embodiment of the present invention;

FIG. 5 is a schematic diagram showing the radiofrequency amplifier circuit based on AF-IMN and AF-OMN provided in an embodiment of the present invention; and

FIG. 6 is a flowchart diagram showing a design method of the asymmetric fishbone-shaped matching network provided in an embodiment of the present invention.

### EMBODIMENTS

To make the purpose, technical solutions and advantages of the present invention clearer, hereinafter a clear and complete description will be given to the technical solutions in embodiments of the present invention in conjunction with the drawings of the present invention, apparently, the embodiments given here are only some embodiments of the present invention rather than all. Based on the embodiments in the present invention, all other embodiments those of ordinary skill in the art obtained without paying creative effort fall into the protection scope of the present invention. Unless defined otherwise, the technical terms or scientific terms used here shall have ordinary meanings apprehensible to those of ordinary skill in the art. Terms such as “including” used in the present invention intend to indicate that the element or article included the listed elements or parts or equivalents thereof, and do not exclude other elements or parts.

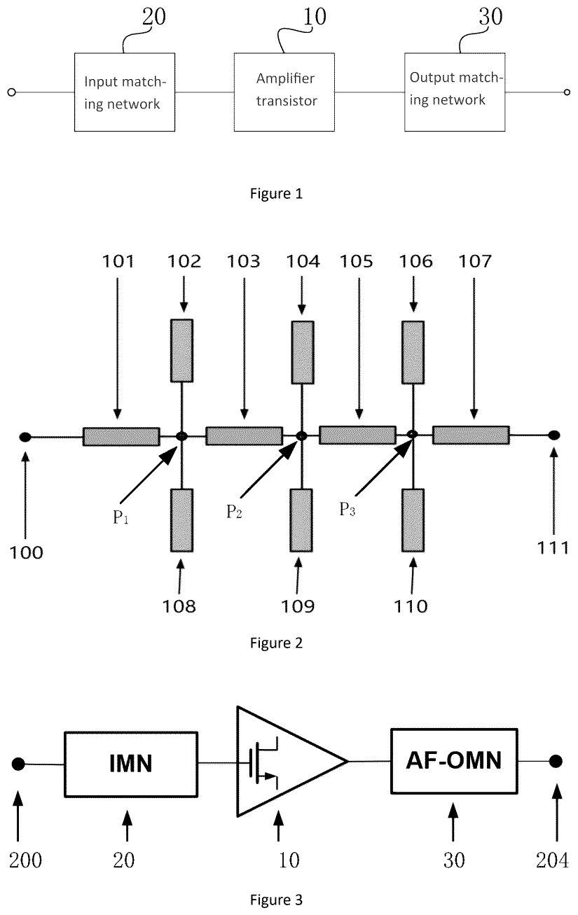

FIG. 1 is an architectural diagram showing a radiofrequency amplifier circuit based on asymmetric fishbone-shaped matching network provided in an embodiment of the present invention. The radiofrequency amplifier circuit comprises: an amplifier transistor 10, an input matching network 20 is connected at an input end of the amplifier transistor 10, and an output matching network 30 is connected at an output end of the amplifier transistor 10, wherein at least one of the input matching network and the output matching network comprises an asymmetric fishbone-shaped structure. The input matching network 20 provides radiofrequency signals and input to the amplifier transistor 10, the radiofrequency signals are amplified by the amplifier transistor 10, output to the output matching network 30 via the output end of the amplifier transistor 10, and finally transmitted to an antenna for emission via the output end of the output matching network 30. In the present embodiment, the amplifier transistor 10 comprises a multi-stage amplifier, for example a three-stage amplifier. Furthermore, in the present embodiment, the input matching network 20 and the output matching network 30 comprise a plurality of network units connected in series.

Wherein, the asymmetric fishbone-shaped structure comprises backbone elements, connection points between neighboring rib elements to connect upper-row rib elements and lower-row rib elements; the upper-row rib elements and the lower-row rib elements are asymmetric; the upper-row rib elements and the lower-row rib elements are configured to be open stub lines, the upper-row rib elements or the lower-row rib elements comprise quarter-wavelength open stubs at the harmonic frequency, and the backbone elements and the rib elements comprise matching network units. Exemplarily, as shown in FIG. 2, the asymmetric fishbone-shaped matching network comprises a backbone element 101, a backbone element 103, a backbone element 105, and a backbone element 107, an upper-row rib element 102, an upper-row rib element 104, an upper-row rib element 106, a lower-row rib element 108, a lower-row rib element 109, and a lower-row rib element 110. Connection points P1, P2 and P3 in between neighboring backbone elements are also called “condyle”, and the input end 100 of the asymmetric fishbone-shaped matching network and the output end 111 of the asymmetric fishbone-shaped matching network are located in both ends of the asymmetric fishbone-shaped matching network respectively. The backbone elements can be inductance or transmission lines. It shall be noted that, during actual application, the number of the rib elements and the backbone elements can be defined as required and is not limited to the number shown in FIG. 2.

For example, with reference to FIG. 3, the present invention proposes a radiofrequency amplifier circuit based on asymmetric fishbone-shaped output matching network (AF-OMN), comprises a signal input end 200, an input matching network (IMN), a biased active amplifier transistor 10, an asymmetric fishbone-shaped output matching network (AF-OMN) 30 and a signal output end 204. Based on the foregoing circuit configuration, the quarter-wavelength open stubs at the harmonic frequency in the asymmetric fishbone-shaped output matching network can reflect the harmonic components in the output signals of the radiofrequency amplifier circuits effectively, and improve the harmonic inhibition features of the radiofrequency amplifier circuit.

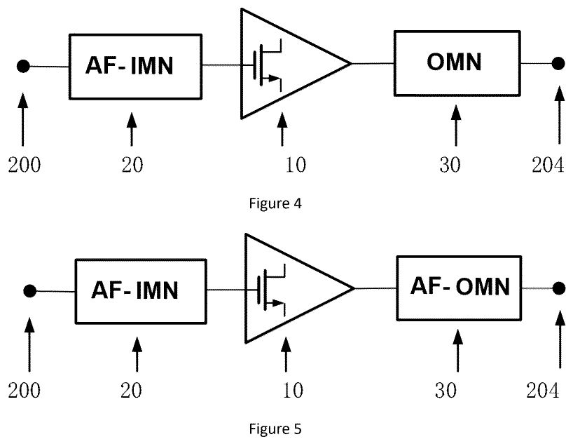

With reference to FIG. 4, the present invention proposes a radiofrequency amplifier circuit based on asymmetric fishbone-shaped input matching network (AF-IMN), comprising a signal input end 200, an asymmetric fishbone-shaped input matching network (AF-IMN) 20, a biased active amplifier transistor 10, a general output matching network 30 and a signal output end 204. Based on the foregoing configuration, the quarter-wavelength open stubs at the harmonic frequency in the asymmetric fishbone-shaped input matching network can reflect the harmonic components in the input signals of the radiofrequency amplifier circuit effectively, which can not only improve the harmonic inhibition features of the radiofrequency amplifier circuit but is also contributive to reduce intermodulation components in the output signals of the radiofrequency amplifier circuit.

With reference to FIG. 5, the present invention proposes a radiofrequency amplifier circuit based on AF-IMN and AF-OMN, that is to say, the input matching network and the output matching network comprise the asymmetric fishbone-shaped structure, comprising a signal input end 200, an asymmetric fishbone-shaped input matching network 20, a biased active amplifier transistor 10, an asymmetric fishbone-shaped output matching network 30 and a signal output end 204. The quarter-wavelength open stub lines at the harmonic frequency in the AF-IMN can reflect the harmonic components in the input signals of the radiofrequency amplifier circuit and the quarter-wavelength open stub lines at the harmonic frequency in the AF-OMN can reflect the harmonic components in the output signals in the radiofrequency amplifier circuit. Based on the foregoing configuration, the harmonic inhibition features and the intermodulation inhibition features in the radiofrequency amplifier circuit can be further improved.

In a possible embodiment, the radiofrequency amplifier circuit further comprises an adjustable capacitor or an adjustable inductor, and one end of the adjustable capacitor or the adjustable inductor is connected in between the amplifier transistor 10 and the antenna and another end thereof is grounded.

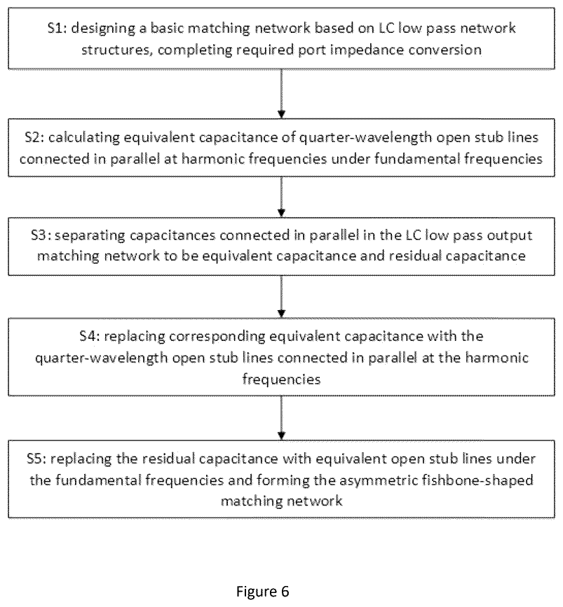

In the present embodiment, the design method of the asymmetric fishbone-shaped matching network is as shown in FIG. 6, comprising:
S1: designing a basic matching network based on LC low pass network structures, completing required port impedance conversion;
S2: calculating equivalent capacitance of quarter-wavelength open stub lines connected in parallel at harmonic frequencies under fundamental frequencies;
S3: separating capacitances connected in parallel in the LC low pass output matching network to be equivalent capacitance and residual capacitance;
S4: replacing corresponding equivalent capacitance with the quarter-wavelength open stub lines connected in parallel at the harmonic frequencies;
S5: replacing the residual capacitance with equivalent open stub lines under the fundamental frequencies and forming the asymmetric fishbone-shaped matching network.

From the foregoing design flow chart, the circuit structure of the asymmetric fishbone-shaped matching network is simple and implementable, and can reduce the complexity of the radiofrequency amplifier circuit effectively.

Above all, the quarter-wavelength open stub lines at the harmonic frequencies in the radiofrequency amplifier circuit based on asymmetric fishbone matching network can reflect the harmonic components in the output signals of the radiofrequency amplifier circuit effectively and improve the harmonic inhibition features of the radiofrequency amplifier circuit.

Although embodiments of the present invention are described in details, it shall be apparent to those skilled in the art that, various modifications and changes can be made to the embodiments. However, it shall be understood that, the modifications and changes fall into the essence and scope of the present invention defined in the claims. Further, the present invention can have other embodiments and can be implemented or realized in a plurality of manners.

1. A radiofrequency amplifier circuit based on asymmetric fishbone-shaped matching network, comprising an amplifier transistor, an input matching network is connected at an input end of the amplifier transistor and an output matching network is connected at an output end of the amplifier transistor; the input matching network and/or the output matching network comprises asymmetric fishbone-shaped structures, the asymmetric fishbone-shaped structures comprise backbone elements connected in series, connection points in between neighboring backbone elements connecting upper-row rib elements and lower-row rib elements; the upper-row rib elements and the lower-row rib elements are asymmetric; the upper-row rib elements and the lower-row rib elements comprise open stub lines, and quarter-wavelength open stub lines at harmonic frequencies and the backbone elements and the rib elements comprise matching network units.

2. The radiofrequency amplifier circuit according to claim 1, wherein all or some of the input matching network and/or the output matching network comprise asymmetric fishbone-shaped structures.

3. The radiofrequency amplifier circuit according to claim 1, wherein the amplifier transistor comprises a biased active amplifier.

4. The radiofrequency amplifier circuit according to any of claims 1-3, wherein the backbone elements comprise capacitance or transmission lines.

5. A design method of the asymmetric fishbone-shaped matching network, for use in forming a radiofrequency amplifier circuit based on asymmetric fishbone-shaped matching network, comprising:
S1: designing a matching network based on LC low pass network structures, completing required port impedance conversion;
S2: calculating equivalent capacitance of quarter-wavelength open stub lines connected in parallel at harmonic frequencies under fundamental frequencies;
S3: separating capacitances connected in parallel in the LC low pass output matching network to be equivalent capacitance and residual capacitance;
S4: replacing corresponding equivalent capacitance with the quarter-wavelength open stub lines connected in parallel at the harmonic frequencies;
S5: replacing the residual capacitance with equivalent open stub lines under the fundamental frequencies and forming the asymmetric fishbone-shaped matching network.
